(19) United States
(12) Patent Application Publication
(10) Pub. No.: US 2026/0181970 A1
(43) Pub. Date: Jun. 25, 2026

(54) METHOD OF MANUFACTURING SILICON CARBIDE POWER DEVICE

(71) Applicant: Hon Hai Precision Industry Co., Ltd., New Taipei City (TW)

(72) Inventors: Weiting LIN, New Taipei City (TW); Yi-Kai HSIAO, New Taipei City (TW); Chia-Lung HUNG, New Taipei City (TW); Wei-Cheng YU, New Taipei City (TW); Hao-Chung KUO, New Taipei City (TW)

(73) Assignee: Hon Hai Precision Industry Co., Ltd., New Taipei City (TW)

(21) Appl. No.: 19/084,628

(22) Filed: Mar. 19, 2025

(30) Foreign Application Priority Data
Dec. 20, 2024 (TW) 113149843

(51) Int. Cl. H10D 62/00; H01L 21/265; H01L 21/324

(52) U.S. Cl. CPC H10D 62/054; H10P 30/204; H10P 30/21; H10P 95/90

(57) ABSTRACT

A method of manufacturing a silicon carbide power device includes performing a first ion implantation process to form a JFET region in an epitaxial layer over a substrate. A patterned mask layer is formed on the epitaxial layer above the JFET region. A second ion implantation process is performed to form well regions at both sides of the JFET region. A first spacer is formed on sidewalls of the patterned mask layer. A third ion implantation process is performed to form a self-aligned heavily doped region in the well regions. A second spacer is formed on a side of the first spacer to shield a portion of the heavily doped region. A fourth ion implantation process is performed to form another self-aligned heavily doped region in the heavily doped region. A gate structure is formed after removing the patterned mask layer, the first spacer, and the second spacer.

### CROSS-REFERENCE TO RELATED APPLICATION

This application claims the priority benefit of Taiwan application serial no. 113149843, filed on Dec. 20, 2024. The entirety of the above-mentioned patent application is hereby incorporated by reference herein and made a part of this specification.

### BACKGROUND

### Technical Field

The disclosure relates to a technology of a silicon carbide power device, and in particular to a method of manufacturing a silicon carbide power device.

### Related Art

Currently, in a process of manufacturing silicon carbide power devices, each ion implantation process requires the use of a corresponding photomask, resulting in high manufacturing costs. Moreover, different ion implantation processes using photomasks may lead to offset issues in the ion implantation regions.

### SUMMARY

The disclosure provides a method of manufacturing a silicon carbide power device, which may be produced in a self-aligned manner and thereby reduce manufacturing costs.

A method of manufacturing a silicon carbide power device according to the disclosure includes the following steps. A substrate is provided to form an epitaxial layer on a surface of the substrate. A first patterned mask layer is formed on a surface of the epitaxial layer, and a portion of the surface is exposed. A first ion implantation process is performed to form a junction field effect transistor (JFET) region in the epitaxial layer. The first patterned mask layer is removed. A second patterned mask layer is formed on the surface of the epitaxial layer and the surface of the epitaxial layer outside the JFET region is exposed. A second ion implantation process is performed to form well regions in the epitaxial layer at both sides of the JFET region. A first spacer is formed on sidewalls of the second patterned mask layer to shield portions of the well regions. A third ion implantation process is performed to form a self-aligned first heavily doped region in the well regions. A second spacer is formed on a side of the first spacer to shield a portion of the first heavily doped region. A fourth ion implantation process is performed to form a self-aligned second heavily doped region in the first heavily doped region. The second patterned mask layer, the first spacer, and the second spacer are removed. A gate structure is formed.

Another method of manufacturing a silicon carbide power device according to the disclosure includes the following steps. A substrate is provided to form an epitaxial layer on a surface of the substrate. A first patterned mask layer is formed on a surface of the epitaxial layer, and a portion of the surface is exposed. A first ion implantation process is performed to form a JFET region in the epitaxial layer. The first patterned mask layer is removed. A second patterned mask layer is formed on the surface of the epitaxial layer, and the surface of the epitaxial layer outside the JFET region is exposed. A second ion implantation process is performed to form well regions in the epitaxial layer at both sides of the JFET region. A first spacer is formed on sidewalls of the second patterned mask layer, and then a second spacer is formed on a side of the first spacer to shield portions of the well regions. A third ion implantation process is formed to form a self-aligned second heavily doped region in the well regions. A third spacer is formed on a side of the second spacer to shield the second heavily doped region. The second spacer is removed to expose the portions of the well regions. A fourth ion implantation process is performed to form a self-aligned first heavily doped region between the second heavily doped region and the JFET region. The second patterned mask layer, the first spacer, and the third spacer are removed. A gate structure is formed.

Based on the above, a self-align way is adopted in the disclosure, which only requires to define the JFET region and the well regions by using a mask at the beginning, while the remaining implantation regions may all be defined by the formation of spacers. Therefore, the process of manufacturing the silicon carbide power device according to the disclosure only consumes two photomasks, thus significantly reducing costs. Moreover, self-alignment achieves ion implantation positioning through spacers, which may effectively reduce the offset of ion implantation regions compared to the photolithography process using photomasks.

To make the aforementioned features of the disclosure more clearly understandable, embodiments are described below with reference to the accompanying drawings as follows.

### BRIEF DESCRIPTION OF THE DRAWINGS

FIG. 1A to FIG. 1J are schematic cross-sectional views of a process flow of manufacturing a silicon carbide power device according to the first embodiment of the disclosure.

FIG. 2A to FIG. 2F are schematic cross-sectional views of a process flow of manufacturing a silicon carbide power device according to the second embodiment of the disclosure.

### DESCRIPTION OF THE EMBODIMENTS

The following embodiments are described in detail with reference to the accompanying drawings, but are not intended to limit the scope covered by the disclosure. In addition, for the convenience, sizes of regions or layers in the drawings are not in actual proportion.

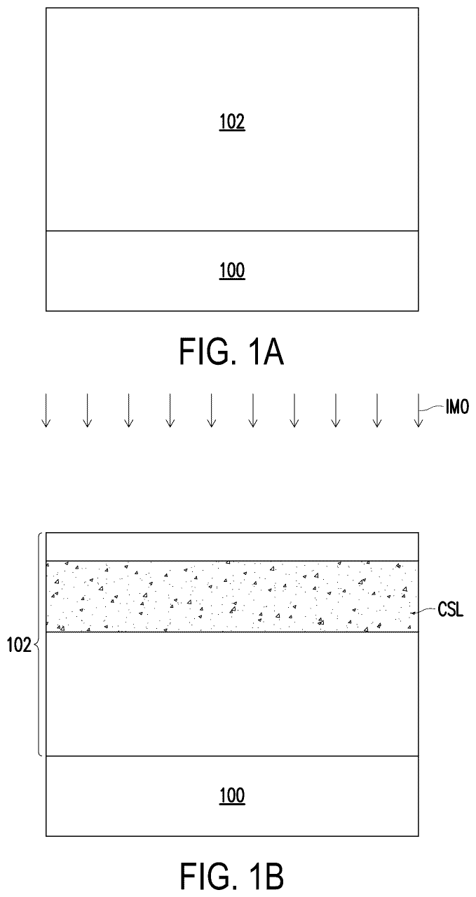

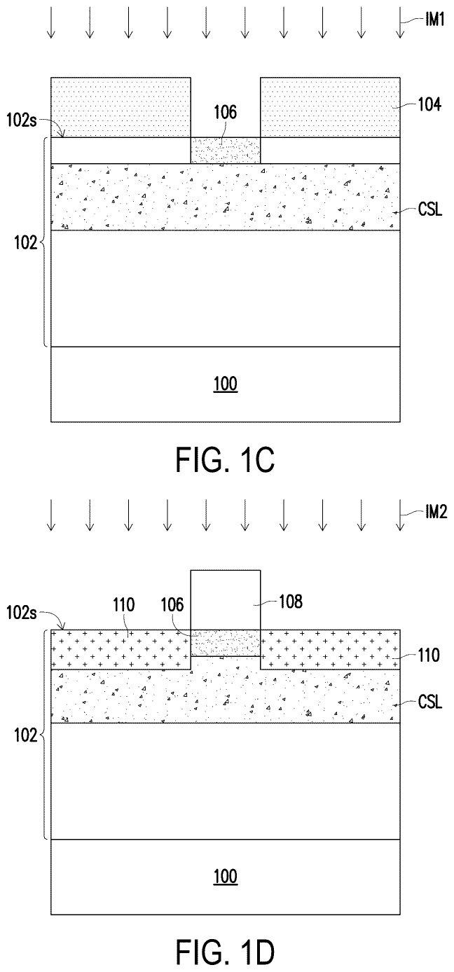

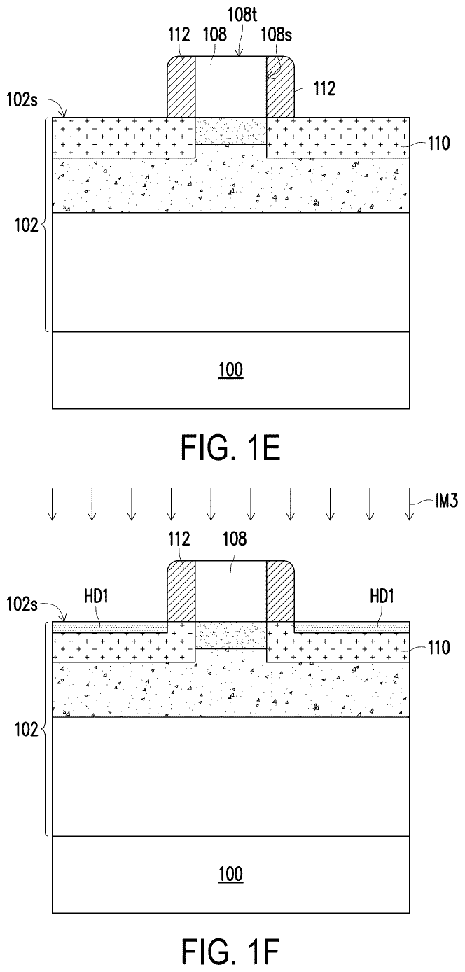

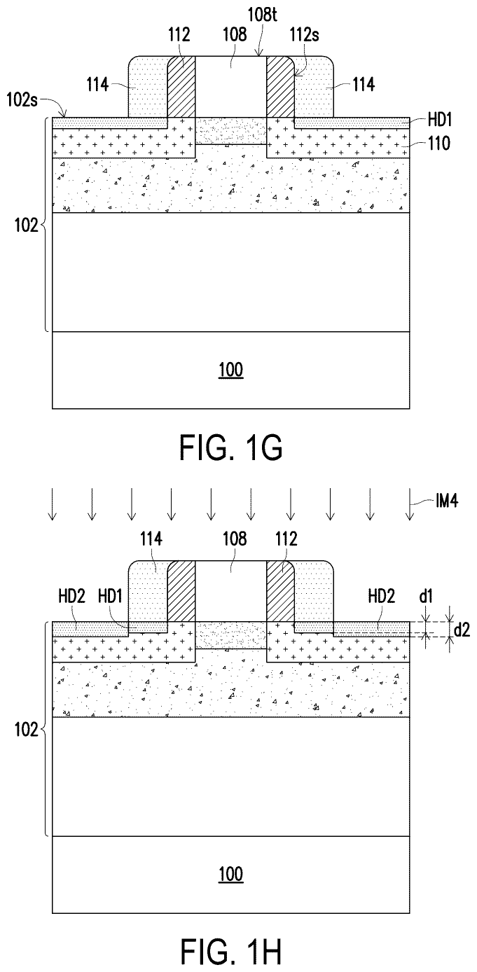

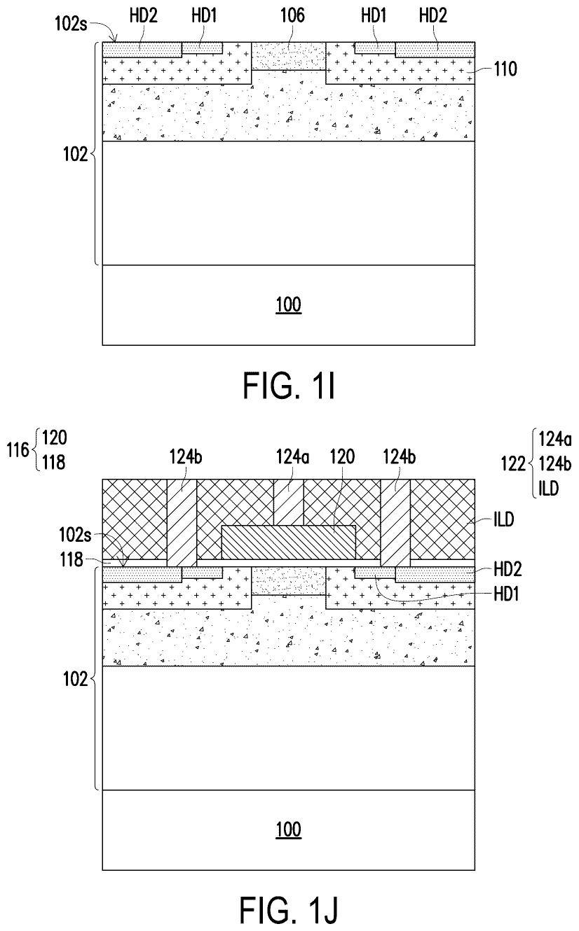

FIG. 1A to FIG. 1J are schematic cross-sectional views of a process flow of manufacturing a silicon carbide power device according to the first embodiment of the disclosure.

Referring to FIG. 1A, a substrate 100 is provided. An epitaxial layer 102 is formed on a surface of the substrate 100. The substrate 100 may be, for example, an N-type silicon carbide substrate, and the epitaxial layer 102 may be, for example, an N-type epitaxial layer.

Next, referring to FIG. 1B, a current spread layer CSL may first be formed in the epitaxial layer 102. In this embodiment, if the epitaxial layer 102 is an N-type epitaxial layer, the current spread layer CSL may be an N-type region. A method of forming the current spread layer CSL includes, but is not limited to, directly performing a CSL ion implantation process IM0 on the epitaxial layer 102 to form a continuous implantation region in the epitaxial layer 102, and a region where the current spread layer CSL is formed is deeper.

Afterwards, referring to FIG. 1C, a first patterned mask layer 104 may be formed on a surface 102s of the epitaxial layer 102, exposing a portion of the surface 102s, and followed by performing a first ion implantation process IM1 to form a junction field effect transistor (JFET) region 106 in the epitaxial layer 102. A method of forming the first patterned mask layer 104 includes, but is not limited to, first depositing a layer of hard mask material over the surface 102s of the epitaxial layer 102 entirely, then performing patterning by a photomask process, to obtain the first patterned mask layer 104 covering the portion of the surface 102s of the epitaxial layer 102. Therefore, the first patterned mask layer 104 may be a hard mask, but is not limited to thereto.

Then, referring to FIG. 1D, a second patterned mask layer 108 is formed on the surface 102s of the epitaxial layer 102, and the surface 102s of the epitaxial layer 102 outside the JFET region 106 is exposed after the first patterned mask layer 104 in FIG. 1C is removed. A method of forming the second patterned mask layer 108 includes, but is not limited to, first depositing a layer of hard mask material over the surface 102s of the epitaxial layer 102 entirely, then performing patterning by a photomask process, to obtain the second patterned mask layer 108 covering the portion of the surface 102s of the epitaxial layer 102. Therefore, the second patterned mask layer 108 may be a hard mask, but is not limited to thereto. Afterwards, a second ion implantation process IM2 is performed to form well regions 110 in the epitaxial layer 102 at both sides of the JFET region 106. In some embodiments, if the epitaxial layer 102 is an N-type epitaxial layer, the well regions 110 may be P-type wells. In some embodiments, lower portions of the well regions 110 may connect with the current spread layer CSL, or extend into the current spread layer CSL.

Next, referring to FIG. 1E, first spacers 112 are formed on the sidewalls 108s of the second patterned mask layer 108 to shield portions of the well regions 110. The second patterned mask layer 108 may be an oxide layer, and the first spacers 112 may be polycrystalline silicon spacers, but are not limited to thereto. In other embodiments, a material of the first spacers 112 may be selected to have etching selectivity with respect to the second patterned mask layer 108. A method of forming the first spacers 112 includes, but is not limited to, first conformally forming a spacer material layer on the surface 102s of the epitaxial layer 102, covering the surface 102s and the sidewalls 108s and top portion 108t of the second patterned mask layer 108, and then performing anisotropic etching on the spacer material layer until the surface 102s of the epitaxial layer 102 is exposed. Due to the process of the first spacers 112, the sizes of the first spacers 112 at both sides of the second patterned mask layer 108 are approximate.

Then, referring to FIG. 1F, a third ion implantation process IM3 is performed to form self-aligned first heavily doped regions HD1 in the well regions 110. As the second patterned mask layer 108 and the first spacers 112 shield the portion of the surface 102s, the first heavily doped regions HD1 are effectively self-aligned in the well regions 110 outside the first spacers 112.

Subsequently, referring to FIG. 1G, second spacers 114 are formed on the sidewalls 112s of the first spacers 112 to shield portions of the first heavily doped regions HD1. If the first spacers 112 are polycrystalline silicon spacers, the second spacers 114 may be oxide spacers, but are not limited to thereto. In other embodiments, a material of the second spacers 114 may be selected to have etching selectivity with respect to the first spacers 112. A method of forming the second spacers 114 includes, but is not limited to, first conformally forming a spacer material layer on the surface 102s of the epitaxial layer 102, covering the surface 102s, the top portion 108t of the second patterned mask layer 108, and the first spacers 112, and then performing anisotropic etching on the spacer material layer until the surface 102s of the epitaxial layer 102 is exposed. Due to the process of the second spacers 114, the sizes of the second spacers 114 at both sides of the first spacers 112 are approximate.

Next, referring to FIG. 1H, a fourth ion implantation process IM4 is performed to form self-aligned second heavily doped regions HD2 in the first heavily doped regions HD1. In some embodiments, a doping concentration of the fourth ion implantation process IM4 may be greater than a doping concentration of the third ion implantation process IM3, to transform the original first heavily doped regions HD1 into second heavily doped regions HD2 with different conductive types. In some embodiments, a doping depth d2 of the second heavily doped regions HD2 may be greater than a doping depth d1 of the first heavily doped regions HD1. In this embodiment, the first heavily doped regions HD1 may be N+ regions, serving as source regions for the subsequently formed silicon carbide power devices, and the second heavily doped regions HD2 may be P+ regions, which may be used to stabilize the potential.

Then, referring to FIG. 1I, the second patterned mask layer 108, the first spacers 112, and the second spacers 114 shown in FIG. 1H are removed. Afterwards, an annealing process may be performed to uniformly diffuse the previously formed doped regions into the required regions and eliminate defects in the implanted regions. As only two photomask processes (that is, forming the first patterned mask layer 104 in FIG. 1C and the second patterned mask layer 108 in FIG. 1D) are required in the five ion implantation processes of this embodiment, the cost may be significantly reduced. Moreover, since the sizes (such as widths) of the spacers at both sides are approximate, there is almost no noticeable discrepancy in the formed first heavily doped regions HD1 and second heavily doped regions HD2.

Next, referring to FIG. 1J, a gate structure 116 is formed. A method of forming the gate structure 116 may include, but is not limited to, first forming a gate insulating layer 118 on the surface 102s of the epitaxial layer 102, and then forming a gate electrode 120 on the gate insulating layer 118. Subsequently, a back-end-of-line (BEOL) structure 122 may be formed. A method of forming the BEOL structure 122 may include, but is not limited to, first forming an inner dielectric layer ILD, and then forming contact windows 124a to 124b in the inner dielectric layer ILD to be electrically connected to the gate electrode 120, the first heavily doped regions HD1, and the second heavily doped regions HD2, respectively.

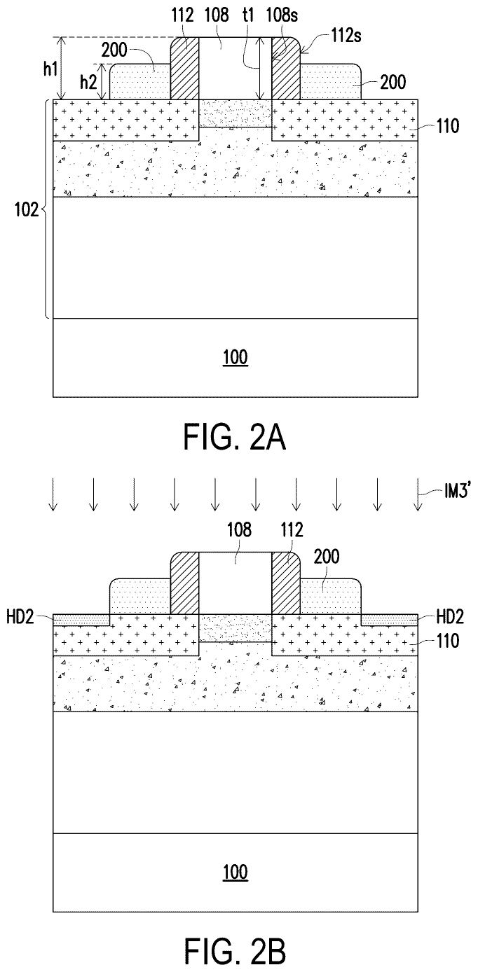

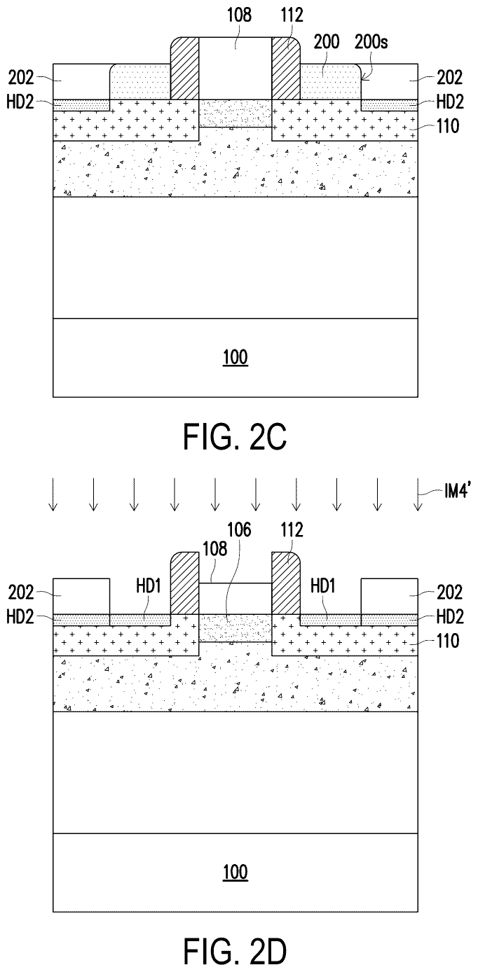

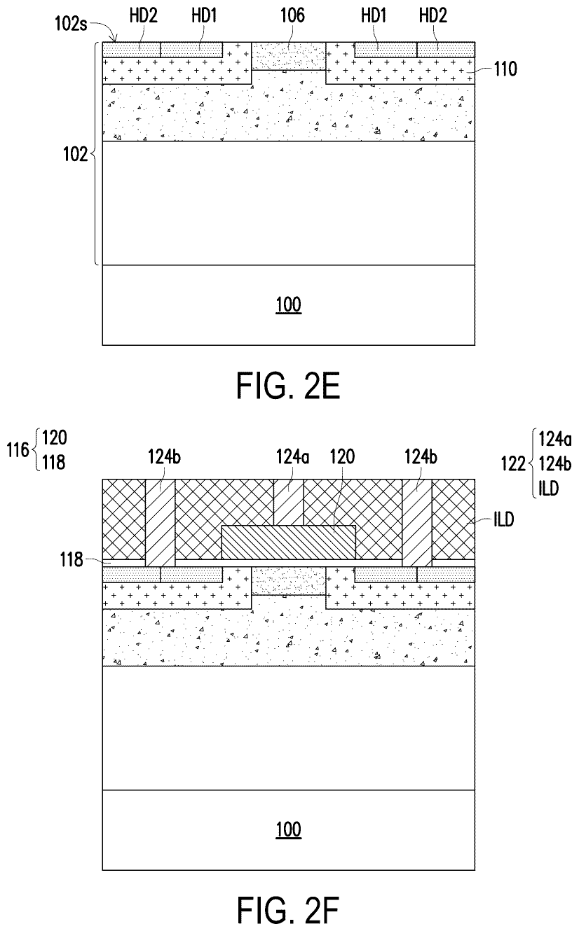

FIG. 2A to FIG. 2F are schematic cross-sectional views of a process flow of manufacturing a silicon carbide power device according to the second embodiment of the disclosure. The method begins from the step following that shown in FIG. 1D, where the formation order of the first heavily doped regions HD1 and the second heavily doped regions HD2 is altered. Moreover, in FIG. 2A to FIG. 2F, the same reference numerals as in the first embodiments are used to represent the same or approximate parts and components, and the relevant description of the same or approximate parts and components may also refer to the description of the first embodiment, which is not repeated here.

Referring to FIG. 2A, after the well regions 110 are formed, the first spacers 112 are formed on the sidewalls 108s of the second patterned mask layer 108, and then the second spacers 200 are formed on the sides 112s of the first spacers 112 to shield the portions of the well regions 110. In some embodiments, the second spacers 200 may be oxide spacers. To accommodate subsequent processes, a height h1 of the first spacers 112 may be greater than a height h2 of the second spacers 200, but is not limited to thereto. In some embodiments, a thickness t1 of the second patterned mask layer 108 is greater than the height h2 of the second spacers 200. A method of forming the second spacers 200 may include, but is not limited to, first conformally forming a spacer material layer on the epitaxial layer 102, and then performing isotropic etching on the spacer material layer until the epitaxial layer 102 is exposed.

Subsequently, referring to FIG. 2B, a third ion implantation process IM3′ is performed to form self-aligned second heavily doped regions HD2 in the well region 110. The third ion implantation process IM3′ is different from the third ion implantation process IM3 in the first embodiment.

Then, referring to FIG. 2C, third spacers 202 are formed on the sides 200s of the second spacers 200 to shield the second heavily doped regions HD2. In some embodiments, if the second spacers 200 are oxide spacers, the third spacers 202 may be nitride spacers or polycrystalline silicon spacers. A method of forming the third spacers 202 may refer to the description above regarding the formation way of the second spacers 200, which is not repeated here.

Next, referring to FIG. 2D, the second spacers 200 in FIG. 2C are first removed to expose the portions of the well regions 110. A method of removing the second spacers 200 may be isotropic etching. During the isotropic etching process, if the second patterned mask layer 108 and the second spacers 200 are both oxide, the second patterned mask layer 108 may also be etched together, but may not be completely removed. Then, a fourth ion implantation process IM4′ is performed to form self-aligned first heavily doped regions HD1 between the second heavily doped regions HD2 and the JFET region 106, and the first heavily doped regions HD1 are separated from the JFET region 106 by a distance. The fourth ion implantation process IM4′ is different from the fourth ion implantation process IM4 in the first embodiment. In some embodiments, since the second heavily doped regions HD2 and the first heavily doped regions HD1 are separately implanted in the well regions 110, the parameters such as doping concentration and doping depth of the fourth ion implantation process IM4′ and the third ion implantation process IM3′ may be adjusted according to requirements, which may make the second heavily doped regions HD2 and the first heavily doped regions HD1 have the same or approximate doping concentration and/or doping depth, but is not limited to thereto.

Subsequently, referring to FIG. 2E, after the second patterned mask layer 108, the first spacers 112, and the third spacers 202 in FIG. 2C are removed, an annealing process may be performed to uniformly diffuse the previously formed doped regions into the required regions and eliminate defects within the implanted regions.

Then, referring to FIG. 2F, according to the process of FIG. 1J, the gate structure 116 is first formed, and then the back-end-of-line (BEOL) structure 122 is formed. In some embodiments, the gate structure 116 includes a gate insulating layer 118 and a gate electrode 120 thereon. In some embodiments, the BEOL structure 122 includes an inner dielectric layer ILD, contact windows 124a to 124b, etc.

In summary, multiple ion implantation processes of the disclosure are proceeded by using a self-aligned way, to reduce the position error of implanted regions caused by exposure, while the cost of making masks in the silicon carbide process is also reduced.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A method of manufacturing a silicon carbide power device, comprising:
providing a substrate to form an epitaxial layer on a surface of the substrate;
forming a first patterned mask layer on a surface of the epitaxial layer and exposing a portion of the surface;
performing a first ion implantation process to form a junction field effect transistor (JFET) region in the epitaxial layer;
removing the first patterned mask layer;
forming a second patterned mask layer on the surface of the epitaxial layer and exposing the surface of the epitaxial layer outside the JFET region;
performing a second ion implantation process to form well regions in the epitaxial layer at both sides of the JFET region;
forming a first spacer on sidewalls of the second patterned mask layer to shield portions of the well regions;
performing a third ion implantation process to form a self-aligned first heavily doped region in the well regions;
forming a second spacer on a side of the first spacer to shield a portion of the first heavily doped region;
performing a fourth ion implantation process to form a self-aligned second heavily doped region in the first heavily doped region;
removing the second patterned mask layer, the first spacer, and the second spacer; and
forming a gate structure.

2. The method of manufacturing the silicon carbide power device according to claim 1, further comprising: forming a current spread layer in the epitaxial layer before forming the JFET region.

3. The method of manufacturing the silicon carbide power device according to claim 2, wherein the epitaxial layer is an N-type epitaxial layer, and the current spread layer is an N-type region.

4. The method of manufacturing the silicon carbide power device according to claim 1, wherein the well region is a P-type well, the first heavily doped region is an N+ region, and the second heavily doped region is a P+ region.

5. The method of manufacturing the silicon carbide power device according to claim 1, wherein the second patterned mask layer is an oxide layer, the first spacer is a polycrystalline silicon spacer, and the second spacer is an oxide spacer.

6. The method of manufacturing the silicon carbide power device according to claim 1, further comprising: performing an annealing process after removing the second patterned mask layer, the first spacer, and the second spacer.

7. The method of manufacturing the silicon carbide power device according to claim 1, wherein a doping depth of the second heavily doped region is greater than a doping depth of the first heavily doped region.

8. The method of manufacturing the silicon carbide power device according to claim 1, wherein a doping concentration of the fourth ion implantation process is greater than a doping concentration of the third ion implantation process.

9. The method of manufacturing the silicon carbide power device according to claim 1, wherein the first patterned mask layer and the second patterned mask layer comprise hard masks.

10. The method of manufacturing the silicon carbide power device according to claim 1, further comprising: forming a back-end-of-line (BEOL) structure after forming the gate structure.

11. A method of manufacturing a silicon carbide power device, comprising:
providing a substrate to form an epitaxial layer on a surface of the substrate;
forming a first patterned mask layer on a surface of the epitaxial layer and exposing a portion of the surface;
performing a first ion implantation process to form a JFET region in the epitaxial layer;
removing the first patterned mask layer;
forming a second patterned mask layer on the surface of the epitaxial layer and exposing the surface of the epitaxial layer outside the JFET region;
performing a second ion implantation process to form well regions in the epitaxial layer at both sides of the JFET region;
forming a first spacer on sidewalls of the second patterned mask layer;
forming a second spacer on a side of the first spacer to shield portions of the well regions;
performing a third ion implantation process to form a self-aligned second heavily doped region in the well regions;
forming a third spacer on a side of the second spacer to shield the second heavily doped region;
removing the second spacer to expose the portions of the well regions;
performing a fourth ion implantation process to form a self-aligned first heavily doped region between the second heavily doped region and the JFET region;
removing the second patterned mask layer, the first spacer, and the third spacer; and
forming a gate structure.

12. The method of manufacturing the silicon carbide power device according to claim 11, further comprising: forming a current spread layer in the epitaxial layer before forming the JFET region.

13. The method of manufacturing the silicon carbide power device according to claim 12, wherein the epitaxial layer is an N-type epitaxial layer, and the current spread layer is an N-type region.

14. The method of manufacturing the silicon carbide power device according to claim 11, wherein the well regions are P-type wells, the first heavily doped region is an N+ region, and the second heavily doped region is a P+ region.

15. The method of manufacturing the silicon carbide power device according to claim 11, wherein the second patterned mask layer is an oxide layer, the first spacer is a polycrystalline silicon spacer, the second spacer is an oxide spacer, and the third spacer is a nitride spacer or a polycrystalline silicon spacer.

16. The method of manufacturing the silicon carbide power device according to claim 11, further comprising: performing an annealing process after removing the second patterned mask layer, the first spacer, and the third spacer.

17. The method of manufacturing the silicon carbide power device according to claim 11, wherein a thickness of the second patterned mask layer is greater than a height of the second spacer.

18. The method of manufacturing the silicon carbide power device according to claim 11, wherein a height of the first spacer is greater than a height of the second spacer.

19. The method of manufacturing the silicon carbide power device according to claim 11, wherein the first patterned mask layer and the second patterned mask layer comprise hard masks.

20. The method of manufacturing the silicon carbide power device according to claim 11, further comprising: forming a BEOL structure after forming the gate structure.
